(19) United States
(12) Patent Application Publication
(10) Pub. No.: US 2009/0166892 A1
(43) Pub. Date: Jul. 2, 2009

(54) CIRCUIT BOARD FOR SEMICONDUCTOR PACKAGE HAVING A REDUCED THICKNESS, METHOD FOR MANUFACTURING THE SAME, AND SEMICONDUCTOR PACKAGE HAVING THE SAME

(76) Inventor: Ki Yong LEE, Seoul (KR)

Correspondence Address: LADAS & PARRY LLP, 224 SOUTH MICHIGAN AVENUE, SUITE 1600, CHICAGO, IL, 60604, US

(21) Appl. No.: 12/260,130

(22) Filed: Oct. 29, 2008

(30) Foreign Application Priority Data
Jan. 2, 2008 (KR) 10-2008-0000299

(51) Int. Cl. H01L 23/485; H05K 1/09; H05K 3/02

(52) U.S. Cl. 257/784; 174/257; 29/847; 257/E23.019

(57) ABSTRACT

A circuit board includes an insulation body having a first surface and a second surface facing away from the first surface. The circuit board comprises a hardened insulation material. Circuit patterns having first conductive surfaces, second conductive surfaces facing away from the first conductive surfaces, and side surfaces connecting the first and second conductive surfaces embedded in the insulation body. That is, the second conductive surfaces and the side surfaces are embedded in the insulation body through the first surface of the insulation body, and the first conductive surfaces are exposed out of the insulation body. Recognition patterns are formed on the second surface of the insulation body.

### CROSS-REFERENCE TO RELATED APPLICATIONS

The present application claims priority to Korean patent application number 10-2008-0000299 filed on Jan. 2, 2008, which is incorporated herein by reference in its entirety.

### BACKGROUND OF THE INVENTION

The present invention relates generally to a circuit board for a semiconductor package, a method for manufacturing the same, and a semiconductor package having the same, and more particularly to a circuit board for a semiconductor package having a reduced volume and/or thickness.

As semiconductor device manufacturing technologies continue to developed, semiconductor packages having semiconductor devices capable of processing an increased amount of data within a short time are necessary.

Semiconductor packages are manufactured through a semiconductor chip manufacturing process that includes forming semiconductor chips on a wafer made of high purity silicon, a die sorting process for electrically inspecting the semiconductor chips, a die attachment process for placing good quality semiconductor chips on boards, and a bonding process for electrically connecting the semiconductor chips to the boards.

Generally, a board for supporting a semiconductor chip has a core, which is made of glass fiber, circuit patterns, which are formed on the surfaces of the core, and solder resist patterns, which cover the circuit patterns.

In the conventional board, decreasing the thickness of the board is difficult because due to the thickness of the core and the presence of the circuit patterns projecting from the surfaces of the core.

### SUMMARY OF THE INVENTION

Embodiments of the present invention include a circuit board for a semiconductor package which does not use a core to be decreased in the thickness thereof.

Further, embodiments of the present invention include a method for manufacturing the circuit board for a semiconductor package.

Also, embodiments of the present invention include a semiconductor package including the circuit board for a semiconductor package.

In one embodiment of the present invention, a circuit board for a semiconductor package comprises an insulation body having a first surface and a second surface facing away from the first surface, and comprising a hardened insulation material; circuit patterns having first conductive surfaces, second conductive surfaces facing away from the first conductive surfaces and side surfaces connecting the first and second conductive surfaces, the second conductive surfaces and the side surfaces being embedded in the insulation body through the first surface of the insulation body, and the first conductive surfaces being exposed out of the insulation body; and recognition patterns placed on the second surface of the insulation body.

The first surface and the first conductive surfaces are placed on substantially the same plane.

The insulation body contains organic substance.

The circuit patterns include thin film patterns and plating patterns which are placed on the thin film patterns.

The circuit patterns contain copper.

The recognition patterns are placed along edges of the second surface of the insulation body.

A volume and an area of the recognition patterns are substantially the same as a volume and an area of the circuit patterns so as to prevent warpage of the insulation body.

The insulation body has a through-opening which passes through the first and second surfaces.

The insulation body contains BT (Bismalemide-Triazine) resin.

The circuit board further comprises first solder resist patterns placed on the first surface and having openings which expose portions of the circuit patterns, and second solder resist patterns placed on the second surface and covering the recognition patterns.

In another embodiment of the present invention, a method for manufacturing a circuit board for a semiconductor package comprises the steps of forming circuit patterns on a buffer substrate; forming a plane insulation body covering the circuit patterns by applying a flowable insulation material on the buffer substrate; and separating the buffer substrate from the circuit patterns and the insulation body.

The step of forming the circuit patterns comprises the steps of placing a metal layer on the buffer substrate using an adhesive; forming photoresist patterns on the metal layer; and patterning the metal layer using the photoresist patterns.

After the step of patterning the metal layer, the method further comprises the step of forming plating patterns on a resultant patterned structure.

In the step of forming the insulation body, the flowable insulation material contains BT (Bismalemide-Triazine) resin.

The method further comprises the step of forming a dummy metal layer on an upper surface of the insulation body.

After the step of forming the dummy metal layer, the method further comprises the step of forming the recognition patterns by patterning the dummy metal layer through a photo process.

The circuit patterns and the dummy metal layer respectively contain copper.

After the step of separating the buffer substrate, the method further comprises the step of decreasing a thickness of the circuit patterns.

After the step of separating the buffer substrate from the insulation body, the method further comprises the steps of forming first solder resist patterns on a first surface of the insulation body formed with the circuit patterns to have openings which expose portions of the circuit patterns, and forming second solder resist patterns on a second surface of the insulation body which faces away from the first surface.

In still another embodiment of the present invention, a semiconductor package comprises a circuit board having an insulation body having a first surface and a second surface facing away from the first surface, and formed by baking a flowable insulation material, circuit patterns having first conductive surfaces, second conductive surfaces facing away from the first conductive surfaces and side surfaces connecting the first and second conductive surfaces, the second conductive surfaces and the side surfaces being embedded in the insulation body through the first surface of the insulation body, and the first conductive surfaces being exposed out of the insulation body, and recognition patterns placed on the second surface of the insulation body; a semiconductor chip placed on the second surface of the insulation body and having bond pads which are exposed through a through-opening defined in the insulation body; and conductive wires electrically connecting the bonding pads and the circuit patterns.

### BRIEF DESCRIPTION OF THE DRAWINGS

FIG. 1 is a plan view showing a circuit board for a semiconductor package in accordance with an embodiment of the present invention.

FIG. 2 is a cross-sectional view taken along the line I-I′ of FIG. 1.

FIGS. 3 through 12 are cross-sectional views showing a method for manufacturing a circuit board for a semiconductor package in accordance with another embodiment of the present invention.

FIG. 13 is a cross-sectional view showing a semiconductor package in accordance with still another embodiment of the present invention.

### DESCRIPTION OF SPECIFIC EMBODIMENTS

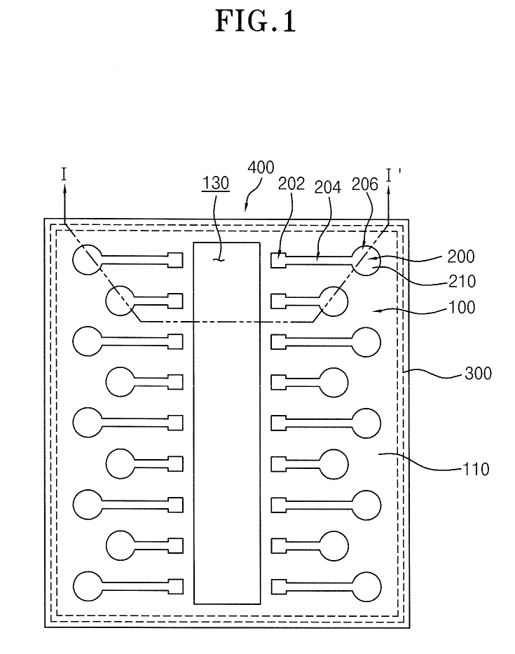

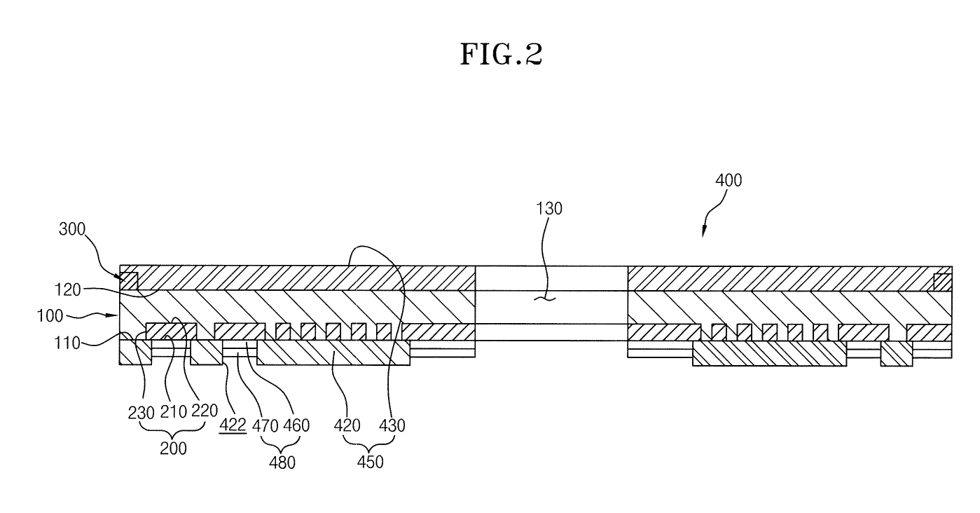

FIG. 1 is a plan view showing a circuit board for a semiconductor package in accordance with an embodiment of the present invention. FIG. 2 is a cross-sectional view taken along the line I-I′ of FIG. 1.

Referring to FIGS. 1 and 2, a circuit board 400 for a semiconductor package includes an insulation body 100, circuit patterns 200, and recognition patterns 300. In addition, the circuit board 400 for a semiconductor package may further include solder resist patterns 450.

The insulation body 100 has the shape of, for example, a plate. The insulation body 100 having the plate shape includes a first surface 110, and a second surface 120 which faces away from the first surface 110. A through-opening 130 is defined at a central portion of the insulation body 100 passing through the first surface 110 and the second surface 120. The through-opening 130 defined at the central portion of the insulation body 100 is defined, for example, in the shape of a slot.

The insulation body 100 may be formed by various methods. For example, the insulation body 100 may be formed by baking a flowable insulation material. In the present embodiment, the insulation body 100 may contain an organic substance. For example, the insulation body 100 may be formed of an insulation material such as Bismalemide-Triazine (BT) resin.

A conventional a printed circuit board includes copper clay lamination (CCL) used as a core. As discussed above, the present invention forms the insulation body 100 through baking a flowable insulation material, and therefore, the insulation body 100 of the present invention has a significantly decreased thickness, when compared to the conventional printed circuit board. Therefore, the volume and the thickness of a semiconductor package can be decreased when the semiconductor package includes the insulation body 100 of the present invention.

The circuit patterns 200 are formed, for example, on the first surface 110 of the insulation body 100. Each circuit pattern 200 has a first conductive surface 210, a second conductive surface 220, and a side surface 230. For example, in the present embodiment the circuit patterns 200 may be thin film patterns formed of a conductive material such as copper.

In the present embodiment, the circuit patterns 200 may be thin film patterns that further include plating patterns (not shown) formed thereon.

According to the present embodiment, the second conductive surface 220 and the side surface 230 of the circuit pattern 200 are embedded in the insulation body 100 and the first conductive surface 210 of the circuit pattern 200 is exposed from the first surface 110 of the insulation body 100. This configuration further decreases the volume and/or the thickness of the circuit board 400 for use in a semiconductor package as compared to a conventional printed circuit board.

In the present embodiment, the first conductive surface 210 of the circuit pattern 200 and the first surface 110 of the insulation body 100 can be placed on substantially the same plane in order to further decrease the thickness of the circuit board 400 for a semiconductor package.

In the case that the first conductive surface 210 of the circuit pattern 200 and the first surface 110 of the insulation body 100 are placed on substantially the same plane, the thickness of the circuit board 400 can be further decreased, and due to this fact, the volume and/or the thickness of the semiconductor package can be further decreased when compared to a printed circuit board which includes CCL used as a core.

Each circuit pattern 200 formed on the first surface 110 of the insulation body 100 may include a connection pad part 202, a junction part 204, and a ball land pattern part 206. In the present embodiment, the connection pad part 202, the junction part 204 and the ball land pattern part 206 are formed integrally with one another.

According to the present embodiment, a plurality of connection pad parts 202 are located on both sides of the through-opening 130 of the insulation body 100. The connection pad parts 202 are electrically coupled to the first ends of respective junction parts 204, and ball land pattern parts 206 are electrically coupled to the second ends of the junction parts 204 which face away from the first ends.

Referring to FIG. 2, the recognition patterns 300 are formed on the second surface 120 of the insulation body 100. The recognition patterns 300 prevent warpage of the insulation body 100.

Referring to FIG. 1, the recognition patterns 300 may be formed along the edges of the second surface 120 of the insulation body 100 in the shape of bars. The recognition patterns 300 may be formed along at least one of the four edges of the insulation body 100.

Therefore, by adjusting the volume and/or the area of the recognition patterns 300 and the volume and/or the area of the circuit patterns 200 to become substantially equal to each other, it is possible to prevent warpage of the insulation body 100.

Referring to FIG. 2, the insulation body 100 may further include solder resist patterns 450.

The solder resist patterns 450 include first solder resist patterns 420 and second solder resist patterns 430.

The first solder resist patterns 420 are formed on the first surface 110 of the insulation body 100, and include openings 422 that expose the connection pad parts 202 and the ball land pattern parts 206 of the respective circuit patterns 200.

In the present embodiment, the volume and/or the thickness of the circuit board 400 for a semiconductor substrate can be additionally decreased because the first conductive surfaces 210 of the circuit patterns 200 are formed on substantially the same plane as both the first surface 110 of the insulation body 100 and the first solder resist patterns 420.

The second solder resist patterns 430 are formed on the second surface 120 of the insulation body 100 and cover the recognition patterns 300. The second solder resist patterns 430, in cooperation with the first solder resist patterns 420, prevent the warpage of the insulation body 100.

Referring to FIG. 2 again, an oxidation barrier layer 480 is formed on the connection pad parts 202 and the ball land pattern parts 206 of the circuit patterns 200, which are formed on the first surface 110 of the insulation body 100 and are exposed through the openings 422 of the first solder resist patterns 420. The oxidation barrier layer 480 prevents the oxidation of the connection pad parts 202 and the ball land pattern parts 206

The oxidation barrier layer 480 may include a nickel layer 460, which is formed on the connection pad parts 202 and the ball land pattern parts 206 of the circuit patterns 200, and a gold layer 470, which is formed on the nickel layer 460. Alternatively, the oxidation barrier layer 480 may include only a gold layer 470 formed on the connection pad parts 202 and the ball land pattern parts 206 of the circuit patterns 200.

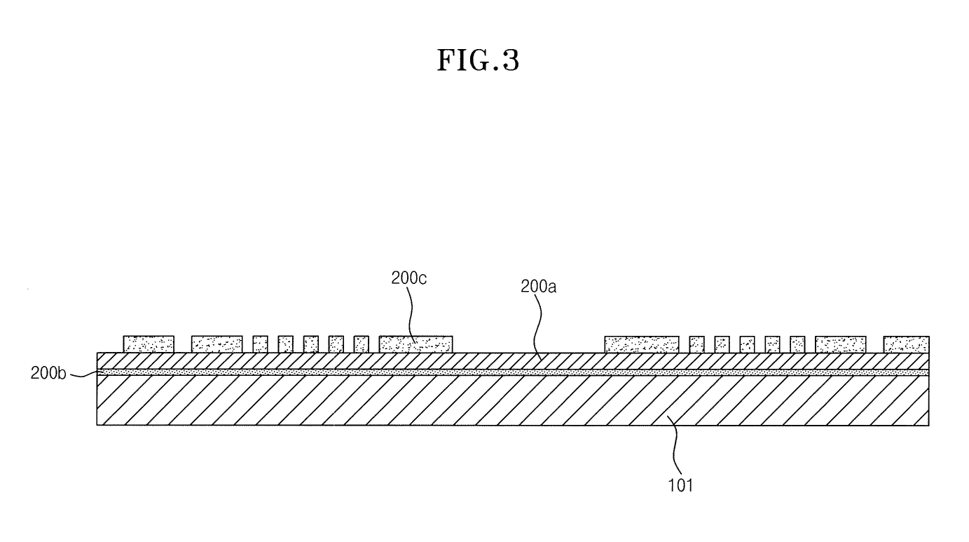

FIGS. 3 through 12 are cross-sectional views illustrating a method for manufacturing a circuit board for a semiconductor package in accordance with another embodiment of the present invention.

FIG. 3 is a cross-sectional view showing the formation of a thin metal film and photoresist patterns on a buffer substrate.

Referring to FIG. 3, a metal layer 200a is formed on a buffer substrate 101. According to the present embodiment, the metal layer 200a includes a copper layer. The metal layer 200a and the buffer substrate 101 may be temporarily attached to each other by an adhesive 200b.

In the present embodiment, the buffer substrate 101 may be formed as any one of various substrates such as a synthetic resin substrate, a glass substrate, a metal substrate, or the like.

After the metal layer 200a is attached to the buffer substrate 101 by the adhesive 200b, or other such medium, photoresist patterns 200c containing photosensitive substance are formed on the metal layer 200a. The photoresist patterns 200c have substantially the same shapes as the circuit patterns 200 shown in FIG. 1 when viewed from the above.

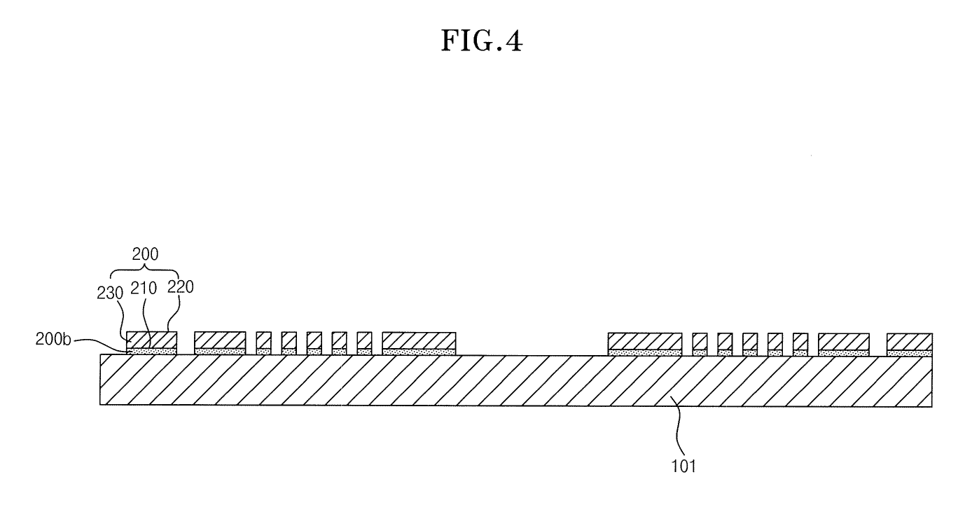

FIG. 4 is a cross-sectional view showing the formation of circuit patterns on the buffer substrate.

Referring to FIG. 4, the metal layer 200a shown in FIG. 3 is patterned using the photoresist patterns 200c as an etch mask to form circuit patterns 200 on the buffer substrate 101. Subsequently, the photoresist patterns 200c formed on the circuit patterns 200 are removed from the circuit patterns 200 through an ashing process or a stripping process.

In the present embodiment, each circuit pattern 200 has a first conductive surface 210, which contacts the buffer substrate 101, a second conductive surface 220, which faces away from the first conductive surface 210, and a side surface 230 which connects the first and second conductive surfaces 210 and 220.

Plating patterns (not shown) may be additionally formed on the circuit patterns 200 through a plating process after the circuit patterns 200 are formed by patterning the metal layer 200a.

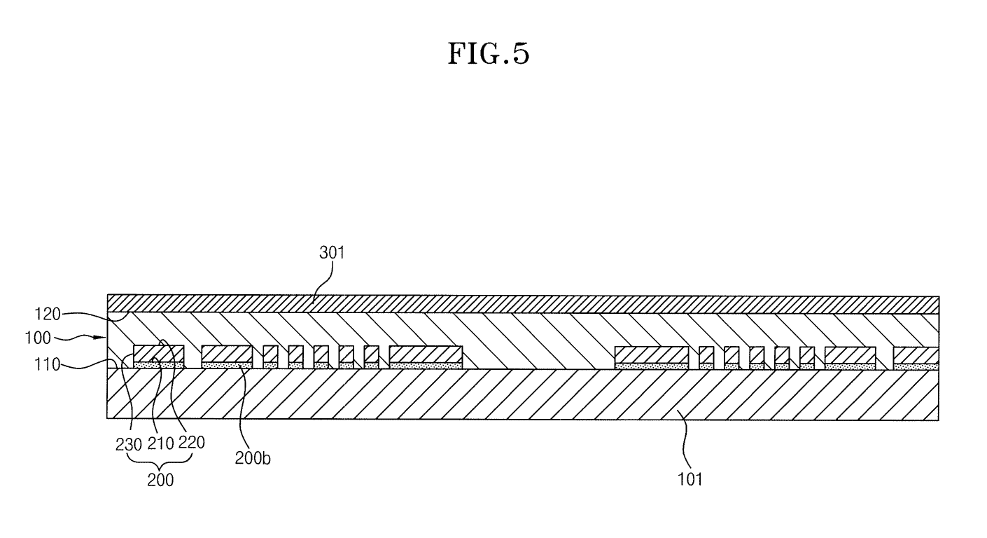

FIG. 5 is a cross-sectional view showing the formation of an insulation body and a dummy metal layer on the circuit patterns shown in FIG. 4.

An insulation body 100 is formed on the buffer substrate 101 to cover the circuit patterns 200 after the circuit patterns 200 are formed on the buffer substrate 101.

The insulation body 100 is formed by applying a flowable insulation material (not shown) on the buffer substrate 101. In the present embodiment, for example, the flowable insulation material may contain an organic substance. Examples of the flowable insulation material include BT resin.

As the flowable insulation material is applied on the buffer substrate 101, the second conductive surfaces 220 and the side surfaces 230 of the circuit patterns 200 are covered by the flowable insulation material. Then, as the flowable insulation material is hardened, the insulation body 100 is formed on the buffer substrate 101.

In the present embodiment, the insulation body 100 has a first surface 110 contacting the buffer substrate 101 and a second surface 120 facing away from the first surface 110. The first and second surfaces 110 and 120 of the insulation body 100 are formed to have planar faces.

As shown in FIG. 5, a dummy metal layer 301 is formed on the second surface 120 of the insulation body 100 after the insulation body 100 is formed on the buffer substrate 101. In the present embodiment, for example, the dummy metal layer 301 may include a copper layer.

In the present embodiment, the dummy metal layer 301 may be formed on a flowable insulation material before the flowable insulation material for forming the insulation body 100 is hardened. Alternatively, the dummy metal layer 301 may be formed on the second surface 120 of the insulation body 100 after the insulation body 100 is formed.

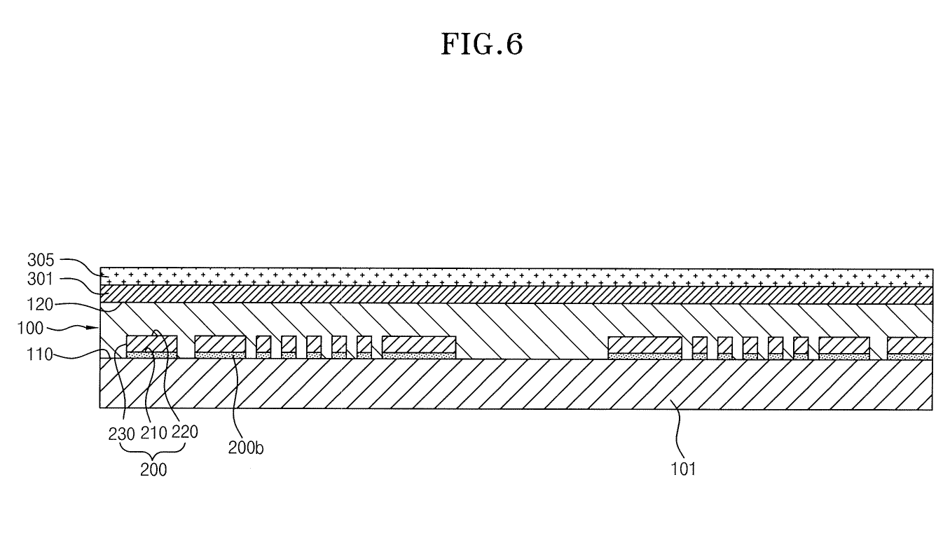

FIG. 6 is a cross-sectional view showing the formation of a mask film on the dummy metal layer shown in FIG. 5.

Referring to FIG. 6, a mask film 305 is formed on the dummy metal layer 301, which is formed on the insulation body 100. According to present embodiment, the mask film 305 may include a dry film containing photosensitive substance or a photoresist film containing photosensitive substance.

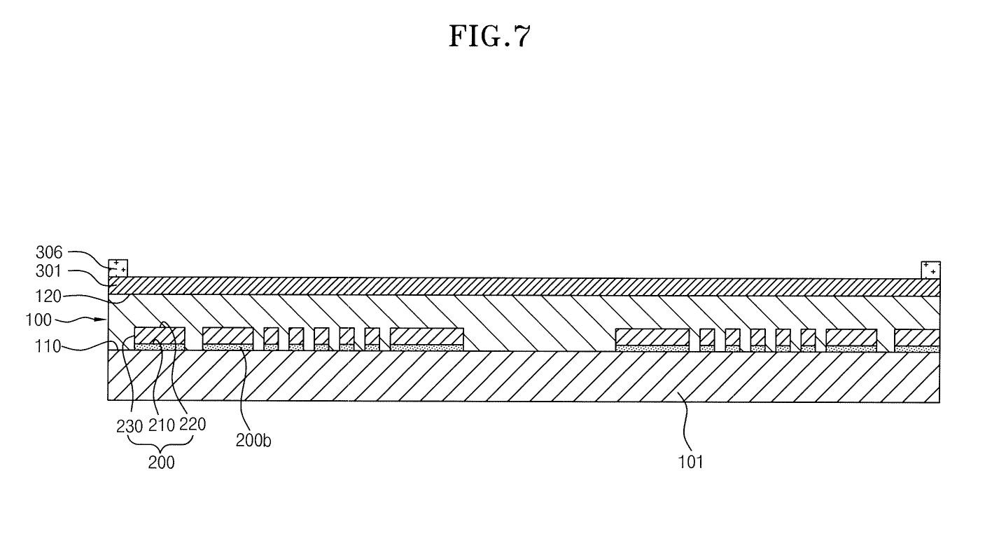

FIG. 7 is a cross-sectional view showing the patterning the mask film, shown in FIG. 6, to form mask patterns.

Referring to FIG. 7, the mask film 305 is patterned through a photo process including a lithographic process and a development process so as to form mask patterns 306 on the dummy metal layer 301.

According to the present embodiment, mask patterns 306 can be formed along the edges of the dummy metal layer 301 in the shape of bars. Alternatively, the mask patterns 306 may be formed on the dummy metal layer 301 in the shape of stripes. As yet another alternative, the mask patterns 306 may be formed on the dummy metal layer 301 in the shape of lattices, or may be formed on the dummy metal layer 301 in the shape of plates. For example, a plurality of mask patterns 306 having the shape of plates can be formed on the dummy metal layer 301 in a matrix pattern.

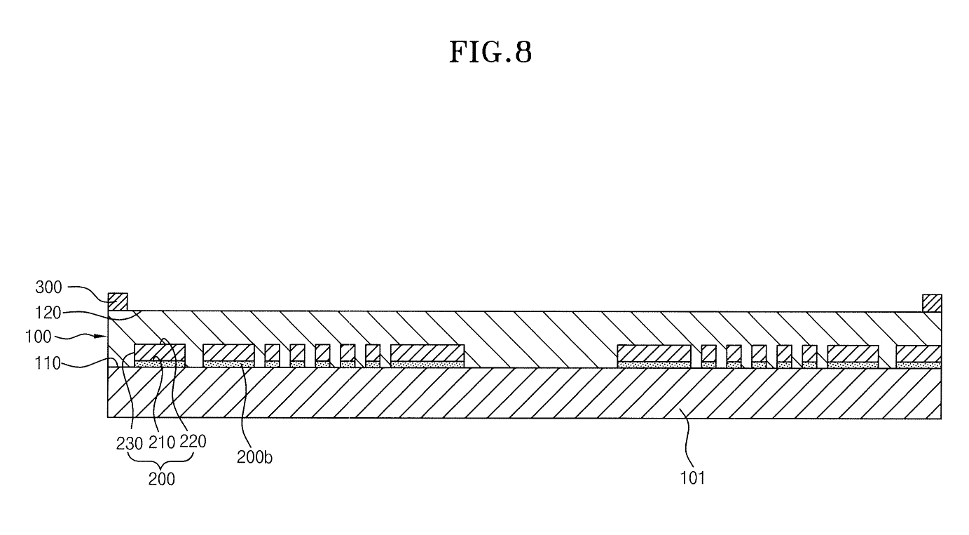

FIG. 8 is a cross-sectional view showing the patterning the dummy metal layer using the mask patterns shown in FIG. 7 to form recognition patterns.

Referring to FIG. 8, the dummy metal layer 301 is patterned using the mask patterns 306 as etch masks, so as to form recognition patterns 300 on the second surface 120 of the insulation body 100.

The recognition patterns 300 may be formed along edges of the insulation body 100 in the shape of bars. Alternatively, the recognition patterns 300 may be formed on the insulation body 100 in the shape of stripes. As another alternative, the recognition patterns 300 may be formed on the insulation body 100 in the shape of lattices. As yet another alternative, the recognition patterns 300 may be formed on the insulation body 100 in the shape of plates. For example, plurality of recognition patterns 300 having the shape of plates may be formed on the insulation body 100 in a matrix pattern.

After the recognition patterns 300 are formed, the mask patterns 306 formed on the recognition patterns 300 are removed from the recognition patterns 300.

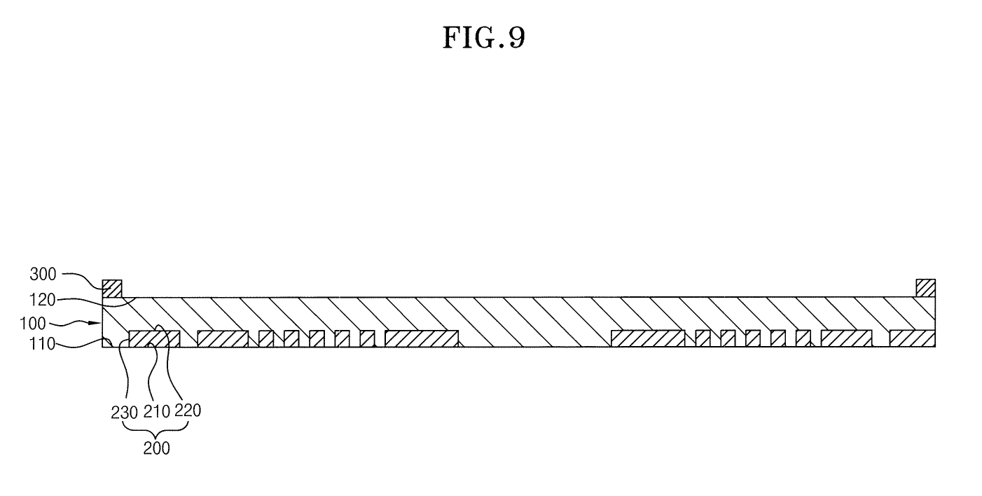

FIG. 9 is a cross-sectional view showing the separation of the buffer substrate from the insulation body.

Referring to FIG. 9, the insulation body 100 is separated from the buffer substrate 101. In order to separate the insulation body 100 from the buffer substrate 101, the adhesive interposed between the buffer substrate 101 and the insulation body 100 can be removed by an etchant or other suitable means.

According to the present embodiment, the first surface 110 of the insulation body 100, which is separated from the buffer substrate 101 may be polished through a polishing process. By the polishing process, the thickness of the insulation body 100 can be additionally decreased.

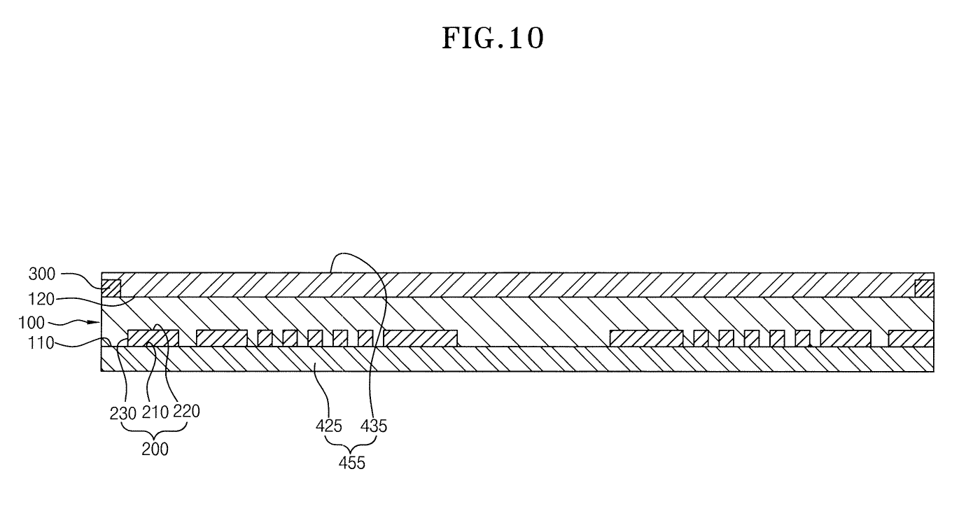

FIG. 10 is a sectional view illustrating the state in which solder resist layers are formed on the insulation body shown in FIG. 9.

Referring to FIG. 10, solder resist layers 455 are formed on the first and second surfaces 110 and 120 of the insulation body 100. That is, according to the present embodiment, a first solder resist layer 425 is formed on the first surface 110 of the insulation body 100 and a second solder resist layer 435 is formed on the second surface 120 of the insulation body 100.

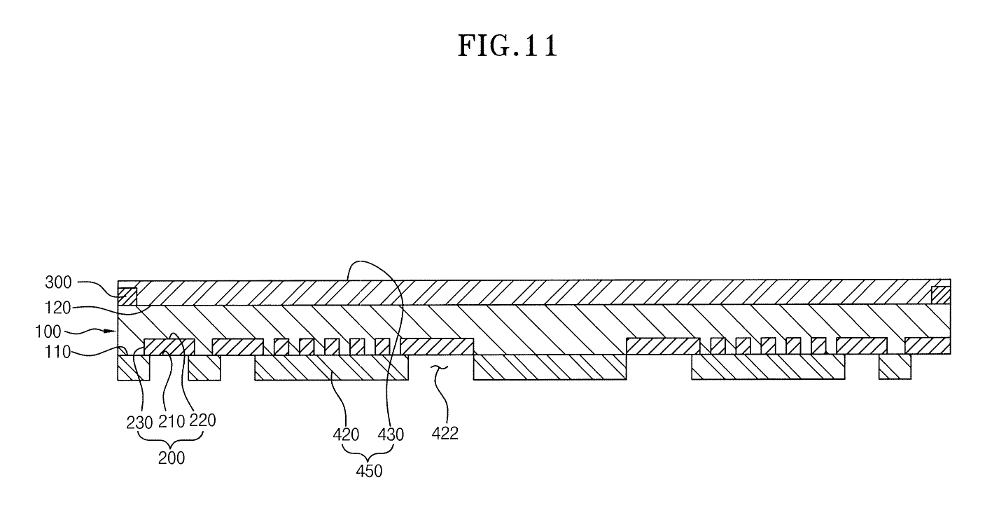

FIG. 11 is a cross-sectional view showing first and second solder resist patterns that are formed by patterning the solder resist layers shown in FIG. 10.

Referring to FIG. 11, first solder resist patterns 420 are formed on the first surface 110 of the insulation body 100 by patterning the first solder resist layer 425. The first solder resist patterns 420 have openings 422 which expose portions of the circuit patterns 200. Second solder resist patterns 430 are formed on the second surface 120 of the insulation body 100.

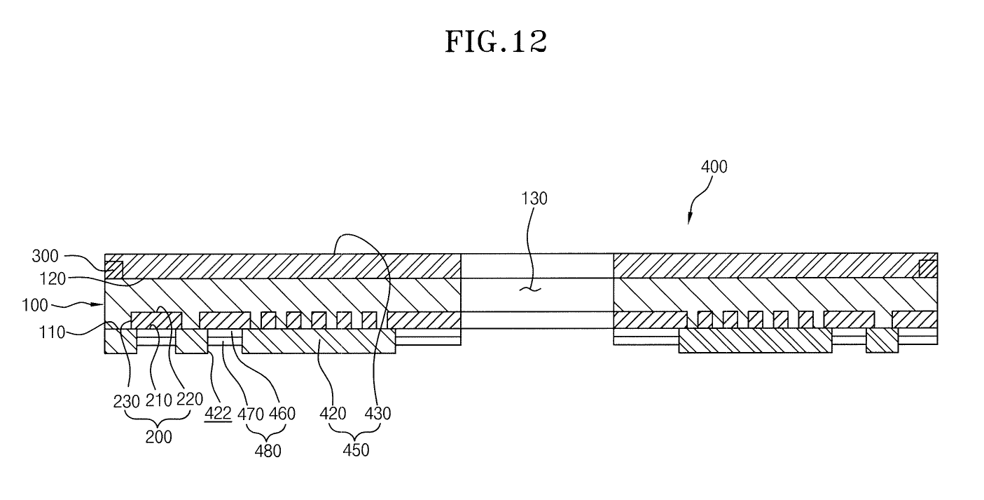

FIG. 12 is a cross-sectional view showing an oxidation barrier layer formed in the openings shown in FIG. 11 and a through-opening.

Referring to FIG. 12, an oxidation barrier layer 480 is formed on the portions of circuit patterns 200 which are exposed through the openings 422 defined in the first solder resist patterns 420. The oxidation barrier layer 480 may include a nickel layer 460 and a gold layer 470. For example, the nickel layer 460 may be formed on the circuit patterns 200, and the gold layer 470 may be formed on the nickel layer 460. Alternatively, the oxidation barrier layer 480 may include only a gold layer 470 formed on the circuit patterns 200.

According to the present embodiment a through-opening 130 is defined at central portions of the insulation body 100 and the solder resist patterns 450 through punching a punching process or the like. The through-opening 130 may have the sectional shape of a slot when viewed from above.

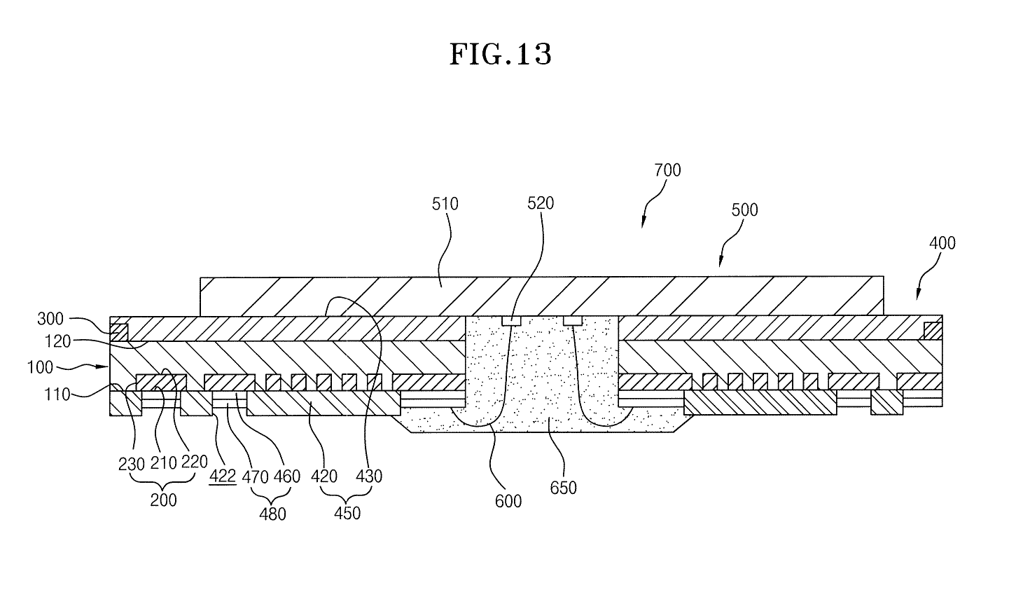

FIG. 13 is a cross-sectional view showing a semiconductor package in accordance with another embodiment of the present invention. As shown in FIG. 13, a circuit board for a semiconductor package has substantially the same construction as that shown in FIG. 2. Therefore, the same reference numerals will be used to refer to the same or like component parts.

Referring to FIG. 13, a semiconductor package 700 includes a circuit board 400, a semiconductor chip 500 and conductive wires 600. In addition, the semiconductor package 700 may include a molding member 650.

The semiconductor chip 500 has a semiconductor chip body 510 and a plurality of bonding pads 520. The semiconductor chip body 510 includes a circuit section (not shown), which has a data storage unit (not shown) and a data processing unit (not shown). The bonding pads 520 are electrically coupled to the circuit section. In the present embodiment, the bonding pads 520 are formed, for example, along a central portion of the semiconductor chip body 510.

The semiconductor chip 500 is disposed on the second solder resist patterns 430 of the circuit board 400, and the bonding pads 520 of the semiconductor chip 500 are formed at positions on the semiconductor chip body 510 corresponding to the through-opening 130 of the circuit board 400.

An adhesive member (not shown) may be interposed between the semiconductor chip 500 and the second solder resist patterns 430.

The conductive wires 600 electrically couple the respective bonding pads 520 of the semiconductor chip 500 to the circuit patterns 200.

The molding member 650 is formed over the conductive wires 600 and the bonding pads 520 which are exposed through the through-opening 130.

As is apparent from the above description, in the present invention, the thickness of a circuit board used in a semiconductor package can be significantly decreased, and therefore the volume and the thickness of a semiconductor package can be greatly decreased.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A circuit board for a semiconductor package, comprising:
an insulation body having a first surface and a second surface facing away from the first surface, wherein the insulation body comprises a hardened insulation material;
circuit patterns comprising:
first conductive surfaces;
second conductive surfaces facing away from the first conductive surfaces; and
side surfaces connecting the first and second conductive surfaces,
wherein the second conductive surfaces and the side surfaces are embedded in the insulation body through the first surface of the insulation body and the first conductive surfaces are exposed out of the insulation body; and
recognition patterns formed on the second surface of the insulation body.

2. The circuit board according to claim 1, wherein the first surface and the first conductive surfaces are formed to be substantially co-planer.

3. The circuit board according to claim 1, wherein the insulation body comprises an organic substance.

4. The circuit board according to claim 1, wherein the circuit patterns comprise:
thin film patterns; and
plating patterns formed on the thin film patterns.

5. The circuit board according to claim 1, wherein the recognition patterns are formed along edges of the second surface of the insulation body.

6. The circuit board according to claim 1, wherein a volume and an area of the recognition patterns are substantially equal to a volume and an area of the circuit patterns so as to prevent warpage of the insulation body.

7. The circuit board according to claim 1, wherein the insulation body has a through-opening which passes through the first and second surfaces.

8. The circuit board according to claim 1, wherein the insulation body comprises Bismalemide-Triazine (BT) resin.

9. The circuit board according to claim 1, further comprising:
a first solder resist patterns formed on predetermined portions of the first surface so as to expose portions of the circuit patterns; and
a second solder resist patterns formed on the second surface covering the recognition patterns.

10. The circuit board according to claim 9, further comprising:
an oxidation barrier layer formed on the exposed portions of the circuit patterns,
wherein the oxidation barrier layer comprises one or more of a nickel layer and a gold layer.

11. A method for manufacturing a circuit board for a semiconductor package, comprising the steps of:
forming circuit patterns on a buffer substrate;
forming an insulation body covering the circuit patterns by applying a flowable insulation material on the buffer substrate; and
separating the buffer substrate from the circuit patterns and the insulation body.

12. The method according to claim 11, wherein the step of forming the circuit patterns comprises the steps of:
forming a metal layer on the buffer substrate using an adhesive;
forming photoresist patterns on the metal layer; and
patterning the metal layer using the photoresist patterns.

13. The method according to claim 12, wherein, after the step of patterning the metal layer, the method further comprises the step of:
forming plating patterns on the patterned metal layer.

14. The method according to claim 11, wherein, in the step of forming the insulation body, the flowable insulation material comprises Bismalemide-Triazine (BT) resin.

15. The method according to claim 11, further comprising the step of:
forming a dummy metal layer on an upper surface of the insulation body.

16. The method according to claim 15, wherein, after the step of forming the dummy metal layer, the method further comprises the step of:
forming the recognition patterns by patterning the dummy metal layer through a photo process.

17. The method according to claim 11, wherein, after the step of separating the buffer substrate, the method further comprises the step of:
decreasing a thickness of the insulation body formed with the circuit patterns.

18. The method according to claim 11, wherein, after the step of separating the buffer substrate from the insulation body, the method further comprises the steps of:
forming a first solder resist pattern on predetermined portions of a first surface of the insulation body formed with the circuit patterns so as to expose portions of the circuit patterns, and
forming second solder resist patterns on a second surface of the insulation body which faces away from the first surface.

19. The method according to claim 18, further comprising:
forming an oxidation barrier layer on the exposed portions of the circuit patterns,
wherein the oxidation barrier layer comprises one or more of a nickel layer and a gold layer.

20. A semiconductor package comprising:
a circuit board comprising:
an insulation body having a first surface and a second surface facing away from the first surface,
wherein the insulation body is formed by baking a flowable insulation material;
circuit patterns having first conductive surfaces, second conductive surfaces facing away from the first conductive surfaces and side surfaces connecting the first and second conductive surfaces,
wherein the second conductive surfaces and the side surfaces are embedded in the insulation body through the first surface of the insulation body and the first conductive surfaces are exposed out of the insulation body; and
recognition patterns formed on the second surface of the insulation body;
a semiconductor chip placed on the second surface of the insulation body and having bond pads which are exposed through a through-opening defined in the insulation body; and
conductive wires electrically coupling the bonding pads to the circuit patterns.
